(19) United States
(12) Patent Application Publication
(10) Pub. No.: US 2013/0026411 A1
(43) Pub. Date: Jan. 31, 2013

(54) PIEZOELECTRIC POLYMER FILM ELEMENT, IN PARTICULAR POLYMER FOIL, AND PROCESS FOR THE PRODUCTION THEREOF

(71) Applicants: Joachim Wagner, Koln (DE); Reimund Gerhard, Berlin (DE); Ing Werner Wirges, Kleinmachnow (DE); Ludwig Jenninger, Gex (FR); Maria Jenninger, Gex (FR)

(72) Inventors: Werner Jenninger, Koln (DE); Joachim Wagner, Koln (DE); Reimund Gerhard, Berlin (DE); Ing Werner Wirges, Kleinmachnow (DE)

(73) Assignee: BAYER INTELLECTUAL PROPERTY GmbH, 40789 Monheim (DE)

(21) Appl. No.: 13/512,361

(22) PCT Filed: Nov. 29, 2010
(86) PCT No.: PCT/EP2010/068369

§ 371 Date: Aug. 1, 2012

(30) Foreign Application Priority Data
Dec. 4, 2009 (EP) 09015050.9

(51) Int. Cl. H01L 41/193; H01L 41/187; H01L 41/22

(52) U.S. Cl. 252/62.9 R; 29/25.35; 264/104

(57) ABSTRACT

The present invention relates to a piezoelectric polymer film element, in particular a polymer foil, comprising a polymer matrix, wherein hollow particles are arranged in the polymer matrix, and a process for the production of such a piezoelectric polymer film element, comprising the steps: A) provision of hollow particles and B) introduction of the hollow particles into a polymer matrix and C) shaping of the polymer matrix as a polymer film. The invention furthermore relates to an electromechanical converter comprising at least one first polymer film which comprises hollow particles as fillers.

The present invention relates to a piezoelectric polymer film element, in particular a polymer foil, comprising a polymer matrix, wherein hollow particles are arranged in the polymer matrix. The invention furthermore relates to a process for the production of a such polymer film elements.

Polymers and polymer composite materials are already being employed in a large number of commercial uses. In this context, functional polymers are gaining increasing importance as active components in sensor or actuator uses. In recent years, a novel class of piezoelectric polymers, the so-called ferroelectrets, have increasingly been of interest in research. The ferroelectrets are also called piezoelectrets. Ferroelectrets comprise polymer materials having a cavity structure which can store electrical charges over long periods of time. Some known ferroelectrets have a cellular cavity structure and are formed either as foamed polymer films or as multilayer systems of polymer films or polymer fabrics. When electrical charges are distributed according to their polarity on the various surfaces of the cavities, each charged cavity represents an electric dipole. If the cavities are now deformed, this causes a change in the dipole size and leads to a current flow between external electrodes. The ferroelectrets can display a piezoelectric activity which is comparable to that of other piezoelectrics.

U.S. Pat. No. 4,654,546 describes a process for the production of polypropylene foamed films as a precursor of a ferroelectret film. In this, filler particles are added to the polymer films. Titanium dioxide, for example, is employed as a filler. After the extrusion, the polypropylene films are stretched biaxially, so that small cavities in the film form around the filler particles. This process has since also been used on other polymers. Thus, for example, in M. Wegener, M. Paajanen, O. Voronina, R. Schulze, W. Wirges and R. Gerhard-Multhaupt “Cavitied cyclo-olefin polymer films: Ferroelectrets with high thermal stability”, Proceedings, 12th International Symposium on Electrets (IEEE Service Center, Piscataway, N.J., USA 2005), 47-50 (2005) and Eetta Saarimäki, Mika Paajanen, Ann-Mari Savijärvi, and Hanna Minkkinen, Michael Wegener, Olena Voronina, Robert Schulze, Werner Wirges and Reimund Gerhard-Multhaupt “Novel Heat Durable Electromechanical Film: Processing for Electromechanical and Electret Applications”, IEEE Transactions on Dielectrics and Electrical Insulation 13, 963-972 (October 2006), the production of ferroelectret films of cycloolefin copolymers (COC) and cycloolefin polymers (COP) has been described. The foamed polymer films have the disadvantage that they can result in a wide distribution of the bubble size. As a result, during the subsequent charging step not all the bubbles may be charged equally well.

Another process for the production of foamed ferroelectret polymer films is the direct physical foaming of a homogeneous film with supercritical liquids, for example with carbon dioxide. This process with polyester materials has been described in Advanced Functional Materials 17, 324-329 (2007), Werner Wirges, Michael Wegener, Olena Voronina, Larissa Zirkel and Reimund Gerhard-Multhaupt “Optimized preparation of elastically soft, highly piezoelectric, cellular ferroelectrets from noncavitied poly(ethylene terephthalate) films”, and in Applied Physics Letters 90, 192908 (2007), P. Fang, M. Wegener, W. Wirges and R. Gerhard L. Zirkel “Cellular polyethylene-naphthalate ferroelectrets: Foaming in supercritical carbon dioxide, structural and electrical preparation, and resulting piezoelectricity”, and for a fluorine polymer FEP (fluorinated ethylene/propylene copolymer) in Applied Physics A: Materials Science & Processing 90, 615-618 (2008), O. Voronina, M. Wegener, W. Wirges, R. Gerhard, L. Zirkel, and H. Münstedt “Physical foaming of fluorinated ethylene-propylene (FEP) copolymers in supercritical carbon dioxide: single film fluoropolymer piezoelectrets”.

In the publications of X. Zhang, J. Hillenbrand und G. M. Sessler, “Thermally stable fluorocarbon ferroelectrets with high piezoelectric coefficient”. Applied Physics A, vol. 84, pp. 139-142, 2006 and “Ferroelectrets with improved thermal stability made from fused fluorocarbon layers”, Journal of Applied Physics, vol. 101, paper 054114, 2007, and in Xiaoqing Zhang, Jinfeng Huang and Zhongfu Xia “Piezoelectric activity and thermal stability of cellular fluorocarbon films” PHYSICA SCRIPTA vol. T129 pp 274-277, 2007, the structuring of the polymer layers by printing a metal grid on to a stack of polymer layers of at least three FEP and PTFE layers positioned one above the other in alternating sequence is described. By pressing together the layers by the grid at a temperature above the melting point of the FEP and below that of PTFE, the polymer layers are bonded to one another according to the grid structure such that dome-shaped or bubble-like cavities with a rectangular base area are formed between the bars of the grid. However, this process leads to ferroelectrets of varying quality, since the formation of uniform cavities can be controlled only with difficulty, above all with an increasing number of layers.

Another process for the production of bubble-like cavities using a grid has been described by R. A. C. Altafim, H. C. Basso, R. A. P. Ahafim, L. Lima, C. V. De Aquino, L. Gonalves Neto and R. Gerhard-Multhaupt in “Piezoelectrets from thermo-formed bubble structures of fluoropolymer-electret films”, IEEE Transactions on Dielectrics and Electrical Insulation, vol. 13, no. 5, pp. 979-985, 2006. In this, two Teflon-FEP films arranged one above the other are arranged between a metal grid and an upper cylindrical metal part. This construction is pressed with the metal grid on to a lower cylindrical metal part which has openings for application of a vacuum. The FEP films are heated through the upper metal part, and the lower film is drawn into the openings of the grid by a vacuum applied to the lower metal part, and corresponding cavities are formed. The processes described using a grid for the formation of cavities in the polymer multilayer composites are involved and difficult to transfer to a large industrial scale.

Piezoelectric materials are furthermore of increasing interest for commercial uses, for example for sensor, actuator and generator systems. In this context, for profitability it is essential that a production process can be used on an industrial scale.

The invention is therefore based on the object of providing novel alternative piezoelectret materials and alternative processes for the production of such piezoelectret materials with which defined piezoelectret cavity structures can be generated and which can also be implemented easily and inexpensively on a large and industrial scale.

According to the invention, a piezoelectric polymer film element, in particular a polymer foil, comprising a polymer matrix, wherein hollow particles are arranged in the polymer matrix, is proposed. In other words, a film of polymer material which contains hollow particles as fillers is provided according to the invention.

A “hollow particle” can be understood as meaning in particular a particle which has a defined shape and a defined cavity volume enclosed therein before introduction into the polymer matrix. Preferably, this shape is essentially retained until the end of the production of the piezoelectric polymer film element according to the invention. Advantageously, the cavity structure, in particular the shape and size of the cavities themselves, can be precisely predetermined in this way. The hollow particles can have, for example, a spherolithic or elongated shape. The cavity volume in the polymer film elements according to the invention, in particular polymer foils, can advantageously be determined precisely by the size and the density of the hollow particles, for example the number of hollow particles per unit area of a polymer film. The distribution of the hollow particles, that is to say the average (maximum) distance of the hollow particles from one another, can be suitably chosen according to the desired properties of the polymer film elements.

In one embodiment of the invention, the hollow particles can be constructed in the form of hollow spheres and/or hollow strands (tubes). Preferably, the hollow particles have the lowest possible size distribution. In particular, the hollow particles can have not only essentially the same height, but also essentially the same size of the diameter of the cavities. In this context, the height of the hollow particles is understood as meaning the (external) height in the direction of the thickness of the polymer film. In this context, “essentially the same height” and “a diameter of essentially the same size” can be understood as meaning that the hollow particles have the same height and/or the same diameter in the context of production tolerance, for example of less than 5%, in particular of less than 1%. If the hollow particles in a polymer film element are configured as uniformly as possible in their size and geometry, the further conditions and properties for the piezoelectric polymer film element, such as, for example, a polarization process or the adjustment of the resonance frequency, can advantageously be optimized particularly well. The size, in particular the height and/or the diameter, of the hollow particles is preferably adjusted in relation to the thickness of the polymer matrix such that the polymer matrix completely surrounds the hollow particles. In particular, the polymer matrix constructed as a polymer film can have continuous flat surfaces.

According to the invention, the volume content of the hollow particles in relation to the polymer matrix can be ≧10 vol. %, preferably ≧15 vol. %, more preferably ≧20 vol. %. According to the invention, however, larger volume contents of the hollow particles in relation to the polymer matrix are possible, for example ≧50 vol. %, or even ≧60 vol. %. According to the invention, the volume contents of the hollow particles and of the polymer matrix in each case add up to 100 vol. %.

The size, in particular the height and/or the diameter, of the hollow particles can preferably be chosen such that after production of the piezoelectric polymer film element according to the invention, the resulting total cavity volume is as large as possible. For example, the hollow particles can have a height of from ≧1 μm to ≦800 μm, in particular from ≧2 μm to ≦300 μm, in particular from ≧5 μm to ≦100 μm, and/or a diameter of from ≧1 μm to ≦500 μm, in particular from ≧2 μm to ≦300 μm, in particular ≧5 μm to ≦100 μm. Preferably, the hollow particles are constructed from an essentially electrically non-conducting and/or electrically non-polarizable material.

The hollow particles can be arranged in the polymer matrix in both homogeneous and heterogeneous distribution. In particular, the hollow particles can be arranged in homogeneous distribution. Depending on a specific field of use for a piezoelectric polymer film element according to the invention and, where appropriate, electromechanical converters to be produced with this, however, it may also be advantageous for the hollow particles to be arranged in a locally resolved heterogeneous distribution, in particular in a targeted manner.

In less preferred embodiments, the hollow particles arranged in the polymer matrix can furthermore be constructed in the same or different shapes. In particular, a plurality of hollow particles constructed in a first shape and a plurality of hollow particles constructed in a second shape and, where appropriate, a plurality of spacer elements constructed in a third shape et cetera can be arranged in the polymer matrix. In this context, the hollow particles constructed in various shapes can in turn be arranged in homogeneous or heterogeneous distribution. In particular, the electromechanical, in particular piezoelectric properties of the piezoelectric polymer film element provided according to the invention can be adapted by the choice of hollow particle shape, hollow particle arrangement and/or hollow particle distribution.

The hollow particles can in principle, where appropriate independently of each other, be constructed from any material which is capable of rendering possible a polarization process in the cavities and of separating and storing the charges formed after the charging process.

In a further embodiment of the piezoelectric polymer film element according to the invention, the hollow particles can be constructed from glass or a polymer or also an essentially electrically non-conducting, electrically non-polarizable ceramic material. For example, the hollow particles can be constructed from mineral glass, in particular silica glass or quartz glass. Polymers for construction of hollow particles according to the invention can be chosen almost as desired. Preferably, polymer materials which are good storers of charge and have good electrical properties are chosen for the hollow particles. As such polymeric materials there may be mentioned by way of example polycarbonates, perfluorinated or partly fluorinated polymers and copolymers, such as PTFE, fluoroethylene-propylene (FEP), perfluoroalkoxyethylenes (PFA), polyesters, such as polyethylene terephthalate (PET) or polyethylene naphthalate (PEN), cycloolefin polymers, cycloolefin copolymers, polyimides, in particular polyetherimide, polyethers, polymethyl methacrylate and polypropylene or polymer blends thereof. Good to very good piezo activities can be achieved with these materials. The wide choice of materials which is provided according to the invention can advantageously also render possible an adaptation to particular uses.

In particular, the hollow particles can be constructed in the form of glass spheres and/or polymer spheres and/or glass strands and/or polymer strands and/or ceramic spheres and/or strands.

In one embodiment of the piezoelectric polymer film element according to the invention, the polymer matrix can be made of an electrically non-conducting polymer or electrically non-conducting polymer mixture, in particular of an elastomer, nonconducting meaning according to the invention that the polymer has a sufficiently high electrical resistance to render possible a suitable polarization process. In a preferred embodiment, the polymer matrix can be made of a polyurethane elastomer, silicone elastomer, acrylate elastomer or rubber or a mixture thereof. With these comparatively soft materials, particularly high piezoelectric constants of the polymer film element according to the invention can be achieved. According to the invention, the rigidity of the polymer matrix can advantageously be adapted in a targeted manner to specific requirements and/or uses.

According to the invention the polymer matrix can be constructed from any material which is capable of rendering possible a polarization process and of separating and storing the charge layers formed in the cavities after the charging process. For example, the polymer matrix can be constructed from at least one polymer chosen from the group consisting of preferably elastomeric rubber derivatives, polyester resins, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes, in particular one- or two-component polyurethane resins or silicone resins, and mixtures of the polymers mentioned, in particular as hinders.

In another embodiment, the polymer matrix of the piezoelectric polymer film element according to the invention, in particular a polymer foil, can have a thickness (D) of from ≧5 μm to ≦1,000 μm, preferably from ≧10 μm to ≦500 μm, for example from ≧20 μm to ≦250 μm.

The invention furthermore relates to a process for the production of a piezoelectric polymer film element, comprising the steps:
A) provision of hollow particles and
B) introduction of the hollow particles into a polymer matrix
C) shaping of the polymer matrix to give the polymer film.

Suitable hollow particles of polymers can be produced, for example, by surrounding a blowing agent, for example isobutane or isopropane, with a chosen polymer material and subsequent controlled heating. For ceramic materials, there is the possibility of using for formation of the cavities in the particles so-called pore-forming agents which can be removed without residue, for example in a sintering process. Alternatively, suitable hollow particles, for example glass hollow spheres, are commercially obtainable from 3M. For example, the glass hollow spheres 3M™ Glass Bubbles K1, 3M™ Glass Bubbles K15, 3M™ Glass Bubbles S38, or 3M™ Glass Bubbles S60 are suitable according to the invention.

The introduction of the hollow particles into the polymer matrix can be carried out, for example, by mixing into the polymer material, for example into granules of a thermoplastic material, which is subsequently melted, or already melted polymer material from which the polymer matrix is formed. The polymer material for the polymer matrix can then subsequently be consolidated, for example dried and/or crosslinked and/or solidified, with the hollow particles distributed therein. This can be carried out, for example, by means of heat, by irradiation with ultraviolet light, by irradiation with infrared light and/or by drying.

For example, the hollow particles provided can be mixed with a first component of a two-component silicone resin and the second component of the silicone resin can subsequently be added to and in turn mixed with this mixture. The polymer material mixture with the hollow particles mixed in can then be further processed by shaping, for example to a polymer film.

The polymer material can also be provided, for example, in dissolved form or with an added solvent, so that the hollow particles are introduced into a polymer material solution or polymer material sufficiently softened by solvent. The consolidation of the polymer material with the hollow particles which have been introduced can subsequently be carried out by drying, that is to say removal of the solvent. Drying can be carried out, for example, by allowing the solvent to evaporate off at room temperature. However, it can also be carried out in an assisted and accelerated manner by means of heat and/or with the aid of a stream of air.

In step C) of the process for the production of the polymer film element according to the invention, the polymer matrix can be formed and/or shaped from a polymer material as a polymer film. The product resulting from the process, that is to say the polymer film element, can be a polymer foil which contains hollow particles as fillers.

In one embodiment, in step C) of the process for the formation and/or shaping of the polymer film element from the polymer material with the hollow particles which have been introduced can be carried out by extrusion or by resin injection moulding.

In the case of thermoplastic polymer materials, however, other known thermoplastic processing methods for shaping of the polymer material to give the polymer film are possible, such as injection moulding.

The formation of the polymer elements, in particular a polymer film according to the invention, can equally be carried out by film-forming processes, such as are also known from lacquer application, for example on a substrate and, where appropriate subsequent detachment of the polymer film from the substrate. Examples of such processes are knife coating, lacquer spin coating, dip coating, spray coating, curtain coating, slot die coating, and/or also roller application processes, for example with roller applicators for hot-melt adhesives from Hardo Maschineribau GmbH (Bad Salzuflen, Germany).

According to the invention, likewise, the polymer matrix is applied, for example, by an abovementioned film-forming process, for example by lacquer spin coating, directly to an electrode, so that subsequent detachment of the polymer film formed can advantageously be omitted. The electrode can be, for example, a metal platelet.

According to the invention, in one embodiment of the process the polymer material for formation of the polymer matrix can comprise at least one polymer, preferably an elastomeric polymer material, chosen from the group consisting of rubber, rubber derivatives, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes and mixtures of these polymers. In particular, one or two component silicone resins or one or two-component polyurethanes can be employed as the polymer material for the polymer matrix.

In one process embodiment according to the invention, charging of the polymer film element with opposite electrical charges can be carried out in a step D). In particular, dipoles are generated in the cavities of the particles by application of a high electrical field.

In a further embodiment of the process according to the invention, this can include application of electrodes to the surfaces of the polymer film element, in particular a polymer foil, as step E).

In the context of the present invention, either first process step D) and then process step E) or first process step E) and then process step D) can be carried out.

The charging in step D) can be carried out, for example, by direct charging, that is to say application of a high electrical field, application of an electrical voltage to the electrodes or by corona discharge. In particular, the charging can be carried out by a two-electrode corona arrangement. In this context, the needle voltage can be at least ≧10 kV, for example at least ≧25 kV, in particular at least ≧30 kV. The charging time in this context can be at least ≧20 s, for example at least ≧30 s, in particular at least ≧1 min.

The electrodes can be applied to the polymer film element in step E) by means of processes known to the person skilled in the art. Possible processes for this are, for example, processes such as, for example, physical vapour deposition (PVD), sputtering and/or vapour deposition, chemical vapour deposition (CVD), printing, knife coating, spin coating. The electrodes can also be glued on in prefabricated form.

The electrode materials can be conductive materials known to the person skilled in the art. Materials which are possible for this are, for example, metals, metal alloys, semiconductors, conductive oligo- or polymers, such as polythiophenes, polyanilines, polypyrroles, conductive oxides or mixed oxides, such as indium tin oxide (ITO), or polymers with a filler content of conductive fillers. Possible fillers for polymers with a filler content of conductive fillers are, for example, metals, such as silver, aluminium and/or copper, conductive carbon-based materials, for example carbon black, carbon nanotubes (CNTs), graphenes or conductive oligo- or polymers. In this context, the filler content of the polymers is preferably above the percolation threshold, which is characterized in that the conductive fillers form continuous electrically conductive paths.

Advantageously, all the process steps of the production process according to the invention can be at least partly automated.

In the context of the present invention, the electrodes can also be structured. For example, the electrodes can be structured such that the piezoelectric polymer element has active and passive regions. In particular, the electrodes can be structured such that in the sensor mode in particular the signals can be detected in a locally resolved manner, and/or in the actuator mode in particular the active regions can be activated in a targeted manner. This can be achieved, for example, if the active regions are provided with electrodes, whereas the passive regions have no electrodes.

The invention furthermore relates to an electromechanical converter comprising at least one first polymer film which comprises hollow particles as fillers.

Preferably, an electromechanical converter according to the invention comprises at least one piezoelectric polymer film according to the invention. This can furthermore comprise at least two electrodes, in particular electrode layers, one electrode contacting the first surface of the polymer film and the other electrode contacting the second surface of the polymer film.

With respect to further features of an electromechanical converter according to the invention, reference is herewith explicitly made to the explanations in connection with the process according to the invention and the use according to the invention.

The present invention also provides the use of a piezoelectric polymer film element or electromechanical converter according to the invention as a sensor, generator and/or actuator, for example in the electromechanical and/or electroacoustic field, in particular in the field of energy production from mechanical vibrations (energy harvesting), acoustics, ultrasound, medical diagnostics, acoustic microscopy, mechanical sensor technology, in particular pressure, force and/or expansion sensor technology, robotics and/or communications technology, in particular in loudspeakers, vibration converters, light deflectors, membranes, modulators for glass fibre optics, pyroelectric, detectors, capacitors and control systems.

With respect to further features of a use according to the invention, reference is herewith explicitly made to the explanations in connection with the process according to the invention and the polymer element according to the invention as well as the electromechanical converter according to the invention.

The invention is explained in the following by way of example in combination with the figures, without being limited to these embodiments.

The figures show:

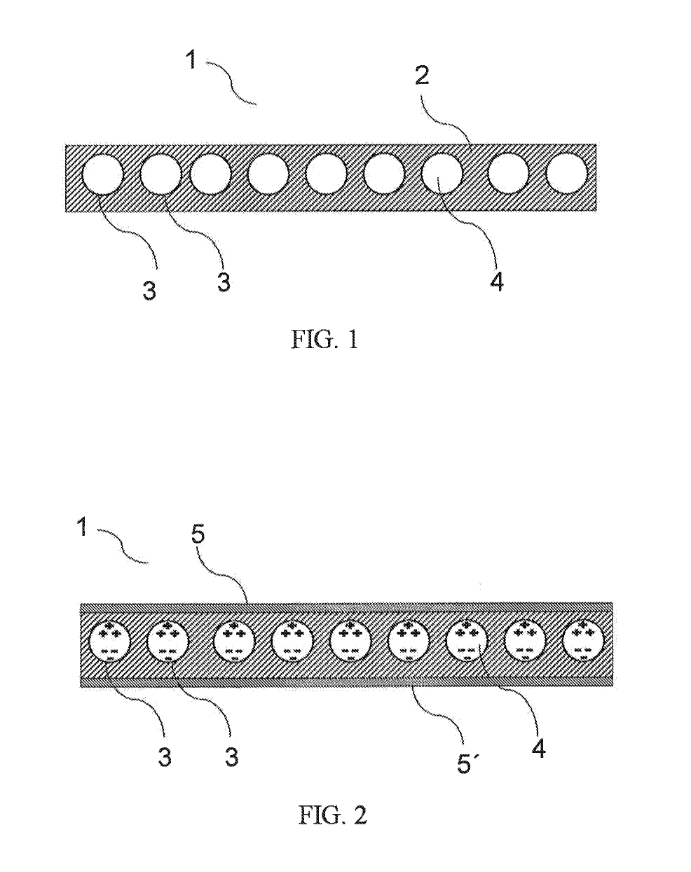

FIG. 1 a diagram of a cross-section through a first embodiment of a polymer film element according to the invention;

FIG. 2 a diagram of a cross-section through another embodiment of a polymer film element according to the invention after polarization.

FIG. 1 shows a diagram of a cross-section through a first embodiment of a piezoelectric polymer film element 1 according to the invention which comprises a polymer matrix 2 and, arranged therein, hollow particles 3 with cavities 4 enclosed therein. For clarity, only nine hollow particles 3 in one layer are shown. The invention is not to be limited by this. According to the invention, the hollow particles 3 can also be arranged in the polymer matrix 2 in random distribution, in several layers, displaced relative to one another and/or one above the other. The hollow particles 3 are configured as hollow spheres and have essentially the same height and essentially the same diameter. In this context, “essentially” means in particular that production-related size and/or height differences are included. In the context of the first embodiment shown for the piezoelectric polymer film element 1 according to the invention, the polymer matrix 2 can be constructed from an elastomeric polymer material. The hollow particles 3 in this context can preferably be constructed from an electrically non-conducting and non-polarizable material, for example from glass, a polymeric material or a ceramic material, and can be mixed into the polymer material before the final shaping of the polymer matrix to a polymer film, for example by extrusion of the chosen polymer material.

FIG. 2 shows a diagram of a cross-section through a further embodiment of the polymer film element 1 according to the invention from FIG. 1. Electrodes 5, 5′ are applied in planar form to the surfaces of the polymer matrix 2. The electrodes 5, 5 can be applied, for example, by physical vapour deposition, sputtering, and/or vapour deposition, chemical vapour deposition, printing, knife coating, spin coating or by gluing on of prefabricated electrodes. In this embodiment, the polymer film element is already polarized, that is to say the cavities 4 of the hollow particles 3 are charged with opposite electrical charges. The polarization can be carried out, for example, by a corona discharge. Advantageously, all the process steps of the production process according to the invention can be at least partly automated.

The invention is to be explained further by the example given in the following, without being limited to this.

### EXAMPLE 1

Production of a piezoelectric polymer film element from a soft elastic polymer matrix and glass hollow spheres introduced therein as a filler.

The Wacker Elastosil RV 625 was used as the polymer matrix material. The Wacker Elastosil material is a two-component silicone resin system. The mixing ratio of component A to component B in the Wacker Elastosil used was A:B=9:1, based on the volume.

Glass hollow spheres, namely 3M™ Glass Bubbles K1 from 3M, were employed as the hollow particles. The ratio of Wacker Elastosil polymer matrix to glass hollow spheres was 83 vol. % to 17 vol. %, the volume contents of polymer matrix material and glass hollow spheres in each case always adding up to 100 vol. %.

The glass hollow spheres were first mixed with component A of the Elastosil in a SpeedMixer at a speed of 2,700 revolutions per minute. Component B of the Elastosil was then added to this and the components were mixed again for one minute in the SpeedMixer at a speed of 2,700 revolutions per minute. The material mixture of polymer matrix material and glass hollow spheres was spin coated on to bronze substrates. The speed during the spin coating was adjusted to between 600 and 1,000 revolutions per minute for 30 to 120 seconds. The samples were than conditioned in an oven at 80° C. for 24 hours. The sample was polarized with a corona needle voltage of −15 kV without a grid. The polymer film was then peeled off from the substrate and the piezoelectric coefficient was measured using the dynamic method at a frequency of 2 Hz. The piezo coefficient was 45 pC/N directly after the polarization.

Experimental set-up for mechanical dynamic measurement of the d33 piezo constants of the piezoelectric polymer film elements produced and measurement procedure.

The following three main components are in principle required for the measuring equipment: energy generator, force sensor and charge meter. An electrical vibration exciter type 4810 from Mid & Kjaer was chosen as the energy generator. The vibration exciter makes it possible to exert a defined force as a function of the input voltage. This vibration exciter was mounted on a movable platform, the position of which is manually adjustable in the vertical direction. The ability to adjust the height of the vibration exciter is necessary for clamping the samples. The static prepressure required for the measurement can also be established by this means. To control the vibration exciter, a function generator DS 345 from Stanford Research Systems was used in combination with a power amplifier type 2718 from Brtiel & Kjaer. A force sensor type 8435 from Burster was used as the force sensor. The force sensor is designed for both pressure and traction measurements in the range of from 0 to 200 N. However, the three should only act perpendicularly, so that no lateral force components or torques act on the sensor. To ensure this, the force sensor was provided with a cylindrical bushing track with a bolt of high-grade steel which slides therein almost friction-free. At the free end of the bolt was a two centimetre wide polished plate which served as a support surface for the samples. The signals from the force sensor are recorded with an amplifier module type 9243 from Burster and transmitted to a GOULD 4094 oscilloscope.

A charge amplifier type 2635 from Brüel & Kjaer was chosen as the charge meter. The charge amplifier makes it possible to record charges down to 0.1 pC. For measurement of the surface charge, the two sides of the sample must be connected electrically to the charge amplifier. The electrical contact to the under-side of the sample is made possible by the support surface, which in its turn is connected to the entire construction. The upper side of the sample was connected to the charge amplifier by the pressure-exerting brass stamp. The stamp is electrically insulated from the remainder of the construction by an attachment of Plexiglas on the vibration exciter, and is connected to the charge amplifier by a cable.

The cable should be as thin and flexible as possible, in order to avoid mechanical stresses and therefore falsifications of the measurement results. Finally, the signal measured is transmitted from the charge amplifier to the oscilloscope. A prepressure of 3 N (static) is set as standard and measured with an amplitude of 1 N (dynamic).

1. A piezoelectric polymer film element comprising a polymer matrix wherein hollow particles are arranged in the polymer matrix.

2. The piezoelectric polymer film element according to claim 1, wherein the hollow particles are in the form of one or more selected from the group consisting of spheres and strands.

3. The piezoelectric polymer film element according to claim 1, wherein the hollow particles are constructed of selected from the group consisting of glass, a polymer and a ceramic material.

4. The piezoelectric polymer film element according to claim 1, wherein the hollow particles have a height of from ≧1 μm to ≦800 μm and/or a diameter of from ≧1 μm to ≦800 μm.

5. The piezoelectric polymer film element according to claim 1, wherein the polymer matrix is made of an electrically non-conducting polymer or an electrically non-conducting polymer mixture.

6. The piezoelectric polymer film element according to claim 1, wherein the polymer matrix is made of an elastomer.

7. The piezoelectric polymer film element according to claim 1, wherein the polymer matrix is made from one or more selected from the group consisting of a polyurethane elastomer, a silicone elastomer, an acrylate elastomer, a rubber and a mixture thereof.

8. The piezoelectric polymer film element according to claim 1, wherein the polymer matrix has a thickness (D) of from ≧10 μm to ≦1,000 μm.

9. A process for the production of a piezoelectric polymer film element comprising:
A) providing hollow particles and
B) introducing the hollow particles into a polymer matrix of a polymer material; and
C) shaping the polymer matrix as a polymer film.

10. The process according to claim 9, wherein the shaping of the polymer film is carried out by one selected from the group consisting of extrusion, resin injection molding, injection molding, knife coating, lacquer spin coating, dip coating, spray coating, curtain coating and slot die coating on to a substrate and, optionally, subsequent detachment of the polymer film from the substrate.

11. The process according to claim 9, wherein the polymer material comprises at least one polymer chosen from the group consisting of rubber, rubber derivatives, unsaturated polyesters, alkyd resins, phenolic resins, amino resins, amido resins, ketone resins, xylene-formaldehyde resins, epoxy resins, phenoxy resins, polyolefins, polyvinyl chloride, polyvinyl esters, polyvinyl alcohols, polyvinyl acetals, polyvinyl ethers, polyacrylates, polymethacrylates, polystyrenes, polycarbonates, polyesters, copolyesters, polyamides, silicone resins, polyurethanes and mixtures of these polymers.

12. The process according to claim 9, further including
D) charging of the polymer film element with opposite electrical charges.

13. The process according to claim 9, further including
E) applying electrodes to one or more surfaces of the polymer film.

14. An electromechanical converter, comprising:
at least one first polymer film which comprises hollow particles as fillers.

15. One of a sensor, a generator and an actuator comprising the polymer film element according to claim 1.

16. One of a sensor, a generator and an actuator comprising the electromechanical converter according to claim 14.

17. The process according to claim 12, wherein the cavities in the hollow particles are charged.
